(19) United States
(12) Patent Application Publication
(10) Pub. No.: US 2022/0157503 A1
(43) Pub. Date: May 19, 2022

(54) COIL MODULE AND ACTUATOR EQUIPPED WITH SAME

(71) Applicant: ROHM CO., LTD., Kyoto-shi, Kyoto (JP)

(72) Inventors: Akihito SAITO, Kyoto-shi, Kyoto (JP); Isamu NISHIMURA, Kyoto-shi, Kyoto (JP); Yoshihiro SEKIMOTO, Kyoto-shi, Kyoto (JP)

(21) Appl. No.: 17/437,801

(22) PCT Filed: Mar. 12, 2020
(86) PCT No.: PCT/JP2020/010722

§ 371 Date: Sep. 9, 2021

(30) Foreign Application Priority Data
Mar. 19, 2019 (JP) 2019-051037

(51) Int. Cl. H01F 7/06; H01F 5/06; H01F 27/28

(52) U.S. Cl. CPC H01F 7/06; H01F 27/2871; H01F 5/06

(57) ABSTRACT

A coil module includes a substrate, a conductor layer, at least one element, and a sealing resin. The substrate includes a semiconductor material. The conductor layer is formed on the substrate and includes a wiring section and a coil section of a helical shape. The at least one element is mounted on the wiring section. The sealing resin covers the obverse surface of the substrate, the conductor layer, and the at least one element. The at least one element includes, for example, a magnetic detection element.

### TECHNICAL FIELD

The present disclosure relates to a coil module. In particular, the present disclosure relates to a coil module suitably used for an actuator.

### BACKGROUND ART

Conventional smartphones include, for example, a camera module. The camera module includes an actuator for driving a lens. The actuator serves, for example, to drive an imaging lens along an optical axis, to perform an autofocus function, or to drive the imaging lens in the direction perpendicular to the optical axis, to perform the optical image stabilization function. Further, the actuator detects the position of the imaging lens, and performs a feedback control based on the detection result, to improve the positioning accuracy, or to quicken the positioning. To enable the actuator to drive the imaging lens, for example an electromagnetic force (Lorentz force), obtained from a combination of a permanent magnet and a coil, is utilized. In this case, the actuator includes the permanent magnet, and a coil module located so as to oppose the permanent magnet.

Patent document 1 discloses an example of the coil module to be used for the actuator in the camera module. This conventional coil module includes a coil substrate, a Hall element, and a flexible substrate. The coil substrate includes a coil formed in a predetermined pattern. The coil substrate and the Hall element are mounted on the flexible substrate. The coil substrate and the Hall element are spaced from each other, so that the Hall element can be exempted from an impact of the distortion of the coil substrate (or stress arising from the distortion). However, the technique to mount the coil substrate and the Hall element separately on the flexible substrate still has a room for improvement, for example in terms of handling of the parts. Besides, it is comparatively difficult to improve the accuracy in relative positioning of the coil substrate and the Hall element.

### PRIOR ART DOCUMENTS

### Patent Document

Patent Document 1: JP-A-2016-192516

### SUMMARY OF THE INVENTION

### Problems to be solved by the Invention

The present disclosure has been accomplished in view of the foregoing situation, and provides a coil module that facilitates the handling of the parts, and can be advantageously employed as a component of the actuator.

### Solution to Problem

In an aspect, the present disclosure provides a coil module including a substrate including a semiconductor material, a conductor layer formed on the substrate, and including a wiring section and a coil section of a helical shape, at least one element mounted on the wiring section, and a sealing resin covering an obverse surface of the substrate, the conductor layer, and the at least one element.

### Advantages of the Invention

The mentioned configuration improves handling efficiency of the parts, and also enables the positional relation between the coil section and the element to be maintained with high accuracy. Further, the substrate formed of the semiconductor material has an appropriate thermal conductivity, and therefore Joule heat, generated by energizing the coil section, can be efficiently dissipated.

Other features and advantages of the present disclosure will become more apparent, through detailed description given hereunder with reference to the accompanying drawings.

### BRIEF DESCRIPTION OF DRAWINGS

FIG. 1 is a perspective view showing a coil module according to a first embodiment.

FIG. 2 is a perspective view showing the coil module of FIG. 1, seen through a sealing resin.

FIG. 3 is an enlarged cross-sectional view taken along a line III-III in FIG. 2.

FIG. 4 includes cross-sectional views each showing a process of a manufacturing method of the coil module shown in FIG. 1.

FIG. 5 includes cross-sectional views each showing a subsequent process of the manufacturing method.

FIG. 6 is a perspective view showing a coil module according to a variation of the first embodiment.

FIG. 7 is a perspective view showing a coil module according to another variation of the first embodiment.

FIG. 8 is an enlarged cross-sectional view taken along a line VIII-VIII in FIG. 7.

FIG. 9 is a perspective view showing a coil module according to a second embodiment.

FIG. 10 is a perspective view showing a coil module according to a third embodiment.

FIG. 11 is a schematic drawing showing distribution of magnetic flux density around a magnetic detection element in the coil module shown in FIG. 10.

FIG. 12 is a perspective view showing a coil module according to a fourth embodiment.

FIG. 13 is a schematic drawing showing distribution of magnetic flux density around a magnetic detection element in the coil module shown in FIG. 12.

FIG. 14 is a perspective view showing a coil module according to a fifth embodiment.

FIG. 15 is a perspective view showing a coil module according to a sixth embodiment.

FIG. 16 is a front view of the coil module shown in FIG. 15.

FIG. 17 is a bottom view of the coil module shown in FIG. 15.

FIG. 18 is a perspective view showing a coil module according to a seventh embodiment.

FIG. 19 is an enlarged cross-sectional view taken along a line XIX-XIX in FIG. 18.

FIG. 20 is a perspective view showing a coil module according to an eighth embodiment.

FIG. 21 is an enlarged cross-sectional view taken along a line XXI-XXI in FIG. 20.

FIG. 22 is a cross-sectional view showing an actuator according to a ninth embodiment.

FIG. 23 is a perspective view showing a coil module appropriate for use in the actuator shown in FIG. 22.

FIG. 24 is a plan view showing an example of an arrangement of the coil module shown in FIG. 23 and another coil component.

### MODE FOR CARRYING OUT THE INVENTION

Hereafter, exemplary embodiments of the present disclosure will be described in detail, with reference to the drawings. The same or similar elements, components, and steps of processing shown in the drawings are given the same numeral, and duplicated description may be skipped. In the following description, the expression “a component A is connected to a component B” implies, in addition to a state where the component A is directly connected to the component B, a state where the component A is indirectly connected to the component B, via another component interposed therebetween.

### First Embodiment

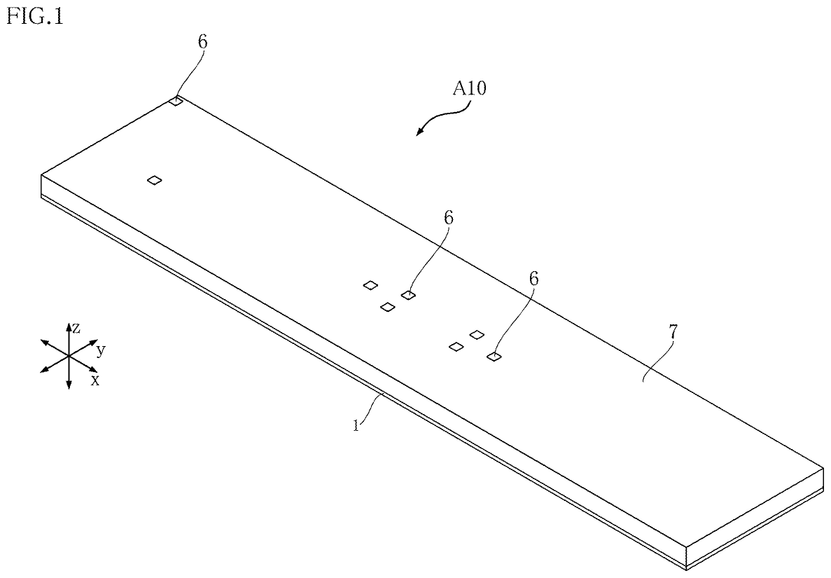

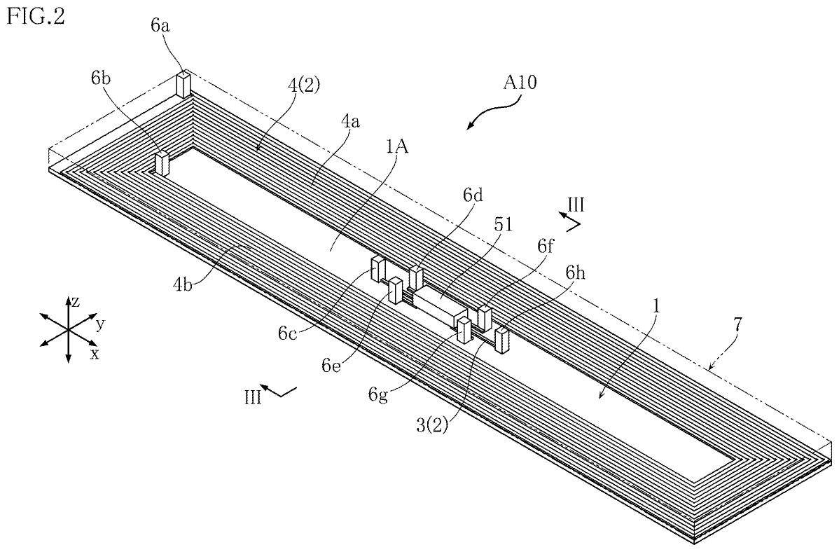

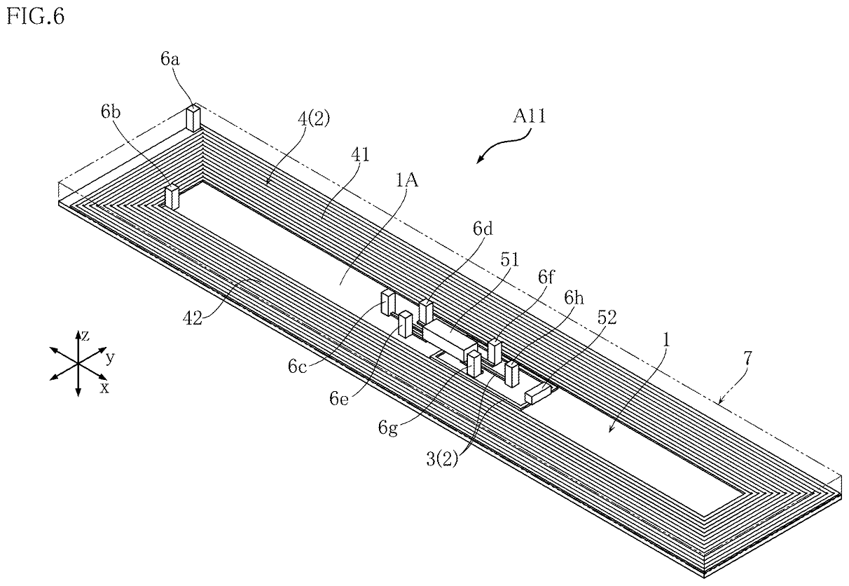

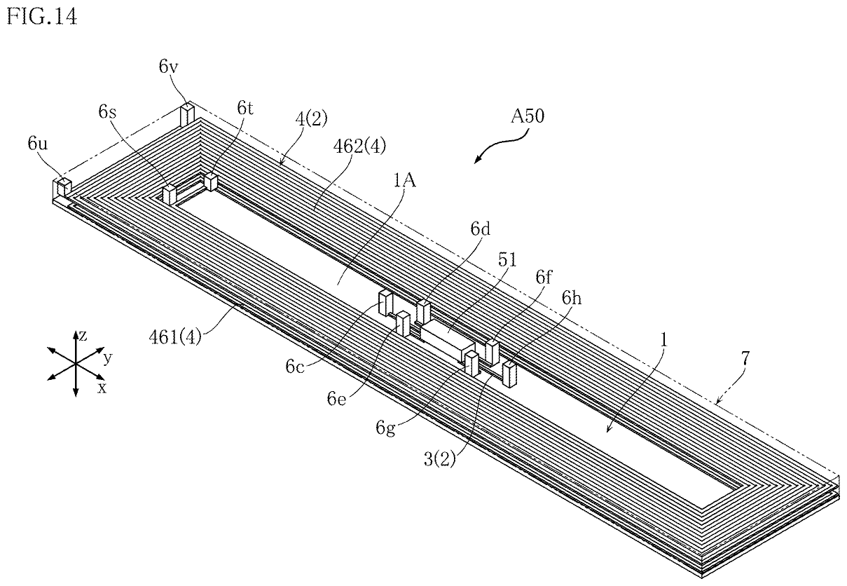

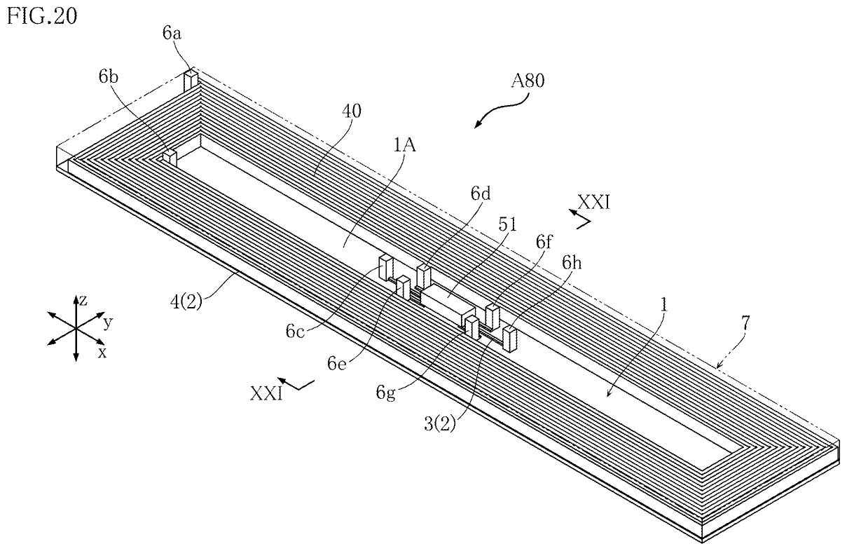

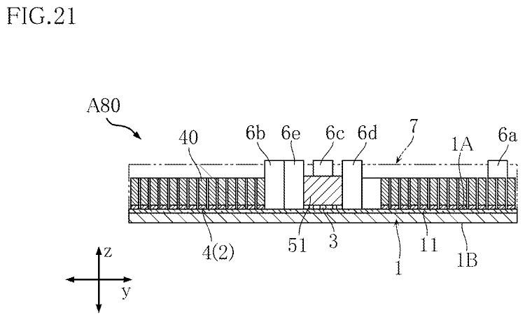

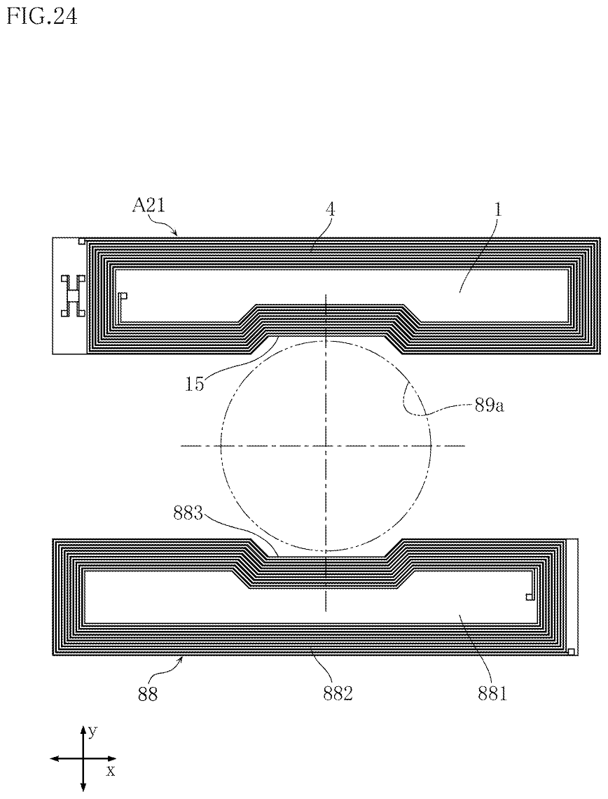

Referring to FIG. 1 to FIG. 3, a coil module A10 according to a first embodiment will be described. The coil module A10 includes a substrate 1, a conductor layer 2, a driver IC 51, a plurality of terminal sections 6 (6a to 6h), and a sealing resin 7. In FIG. 2, the coil module A10 is seen through the sealing resin 7 (see dash-dot-dot lines). In FIG. 6 to FIG. 10, FIG. 12, FIG. 14 to FIG. 17, FIG. 20, FIG. 21, and FIG. 23, to be subsequently referred to, the sealing resin 7 is also indicated by dash-dot-dot lines.

The coil module A10 is suitable for constituting an actuator, for example by being located so as to oppose a magnetic field generator. An example of the magnetic field generator is a permanent magnet. Although the illustrated coil module A10 has a rectangular parallelepiped shape, the present disclosure is not limited thereto. As an example, the length of the long sides (extending along an x-direction) of the coil module A10 is approximately 3 to 6 mm, the length of the short sides (extending in a y-direction) is approximately 1.5 to 2.5 mm, and the thickness (size in a z-direction) is approximately 1 to 2 mm. Hereinafter, the z-direction may be referred to as “thickness direction”, where appropriate. In addition, “a view in the z-direction (view in the thickness direction)” may be expressed as “in a plan view”, where appropriate.

The substrate 1, which serves as the base of the coil module A10, includes a semiconductor material. The substrate 1 has an elongate rectangular shape, and includes an obverse face 1A and a reverse face 1B. The obverse face 1A and the reverse face 1B are oriented in opposite directions to each other, in the z-direction (in other words, the obverse face 1A and the reverse face 1B are spaced from each other in the z-direction). The thickness of the substrate 1 is, for example, approximately 50 μm.

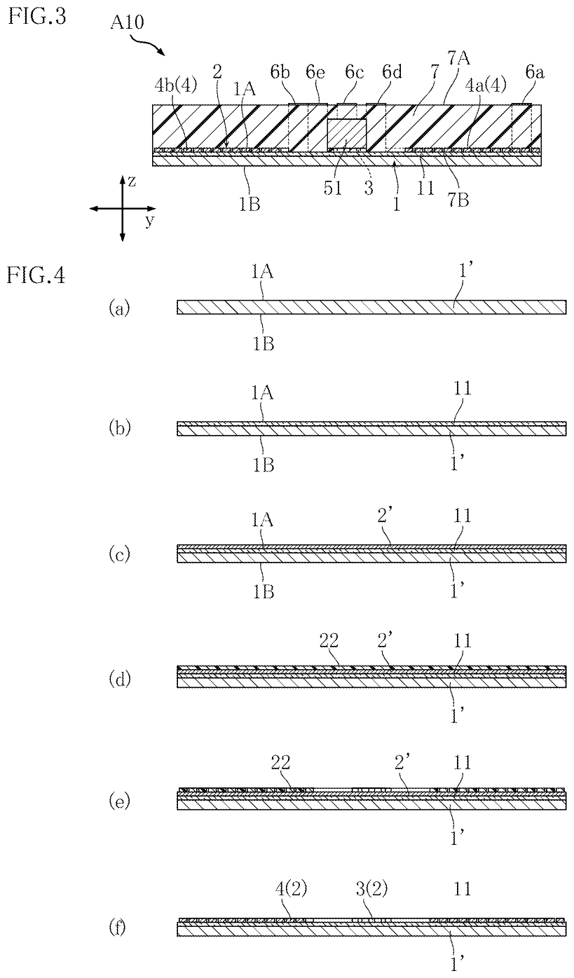

In this embodiment, an insulation layer 11 is formed on the obverse face 1A of the substrate 1, as shown in FIG. 3. As will be subsequently described in further detail, the insulation layer 11 is constituted of an oxide film formed on the obverse face 1A of the substrate 1.

The conductor layer 2 is formed on the substrate 1, and includes a wiring section 3 and a coil section 4 (see FIG. 2). More specifically, the conductor layer 2 is patterned on the substrate 1, via the insulation layer 11 (see FIG. 3) therebetween. In this embodiment, the wiring section 3 and the coil section 4 constituting the conductor layer 2 are formed in the same layer.

As shown in FIG. 2, the coil section 4 is patterned in a helical shape, having a rectangular outer peripheral edge and a rectangular inner peripheral edge. A part of the substrate 1 (obverse face 1A) is exposed from an opening defined by the inner peripheral edge of the coil section 4. As viewed in the z-direction, the coil section 4 is formed in a region having a generally constant width, from the outer peripheral edge (or a position close thereto) of the substrate 1. A driver IC 51 is mounted on the wiring section 3, and thus the wiring section 3 constitutes a current path that leads to the driver IC 51. The wiring section 3 is formed inside the coil section 4, as viewed in the z-direction. In the illustrated example, the wiring section 3 includes a plurality of wiring elements separated from each other, according to the number of terminals of the driver IC 51. Hereinafter, each individual wiring element may be referred to as “wiring section” for the sake of simplicity of description, and the individual wiring element is also given the numeral “3”, equally to the wiring section.

The driver IC 51 is an integrated circuit in which a magnetic detection element (e.g., Hall element) is mounted. The driver IC detects the intensity of a magnetic field (magnetic flux density) incident on the magnetic detection element, and supplies a current to the coil section 4. The driver IC 51 is located inside the coil section 4 in its entirety, as viewed in the z-direction.

In this embodiment, the driver IC 51 is formed as a chip of an elongate shape. A space of an elongate rectangular shape is defined inside the coil section 4, and therefore locating the driver IC 51 in this space leads to effective utilization of the inner space of the coil module A10.

When the coil module A10 is employed as the component to constitute the actuator, the magnetic detection element of the driver IC 51 detects relative displacement with respect to the magnetic field generator, and feeds back the signal obtained as result of the detection. Then the driver IC 51 drives the movable section of the actuator, so as to realize a desired amount of the relative displacement, according to the signal (feedback signal). To be more detailed, the driver IC 51 supplies a current of a predetermined amount to the coil section 4, according to the feedback signal. As shown in FIG. 2, the coil section 4 includes two sections extending in the longitudinal direction, namely a first section 4a and a second section 4b. On the first section 4a and the second section 4b, magnetic fluxes of different directions (e.g., magnetic fluxes of opposite directions to each other along a plane including the coil section 4), generated by the magnetic field generator, are respectively incident. When the coil section 4 is energized under such condition, Lorentz force is generated from the interaction between the magnetic flux and the current, and such Lorentz force serves as the driving force of the actuator.

In this embodiment, the plurality of terminal sections 6a to 6h are each electrically connected to one of the wiring section 3 and the coil section 4. The terminal sections 6a to 6h each extend in the z-direction, from the wiring section 3 or the coil section 4. To be more detailed, the terminal sections 6a and 6b are located at the respective ends of the coil section 4, as shown in FIG. 2. The terminal sections 6c to 6h are provided so as to respectively correspond to the wiring section (wiring elements) 3. In this embodiment, the wiring section 3 includes six wiring elements, and the terminal sections 6c to 6h are each connected to one end of the corresponding wiring element 3. The other end of each of the wiring elements 3 is connected to the terminal of the driver IC 51. To connect the wiring section (wiring elements) 3 and the driver IC 51, for example a solder bump or a gold bump (not shown) are employed. In this case, the driver IC 51 can be positioned with high accuracy, by self-alignment based on the surface tension of the molten metal.

Out of the six terminal sections 6c to 6h, four (e.g., terminal sections 6d, 6e, 6f, and 6g) are for the power source, ground, a clock, and a signal, respectively, and the remaining two (e.g., terminal sections 6c and 6h) are respectively connected to the terminal sections 6a and 6b of the coil section 4. When connecting, for example, the terminal section 6a and the terminal section 6c, and the terminal section 6b and the terminal section 6h, a current path formed in the coil module A10 may be utilized for the connection. In this case, the current path has to be routed so as to stride over the coil section 4, to connect the terminal section 6a and the terminal section 6c. Therefore, the coil module A10 has to be formed in a multilayer structure, for example by adding an insulation layer. In the case where the multilayer structure is not adopted, the terminal section 6a and the terminal section 6c can be connected, via the wiring pattern formed on a flexible substrate, on which the coil module A10 is mounted.

As shown in FIG. 3, the sealing resin 7 is formed on the substrate 1, so as to cover the obverse face 1A of the substrate 1, the conductor layer 2 (wiring section 3 and coil section 4), and the driver IC 51. The sealing resin 7 includes a top face 7A and a bottom face 7B. The bottom face 7B covers the substrate 1. The top face 7A is oriented to the same side as the obverse face 1A of the substrate 1 in the z-direction, and to the opposite side of the bottom face 7B.

The sealing resin 7 covers the major part of the terminal sections 6a to 6h, except for the tip portion thereof. The tip portion of each of the terminal sections 6a to 6h is exposed to outside, from the top face 7A of the sealing resin 7. In the sealing resin 7, the top face 7A serves as the mounting surface via which the coil module A10 is mounted, for example, on the flexible substrate in the actuator.

The sealing resin 7 may be either a transparent resin or a non-transparent resin. The material of the sealing resin 7 is not specifically limited. For example, an epoxy resin may be employed to form the sealing resin 7.

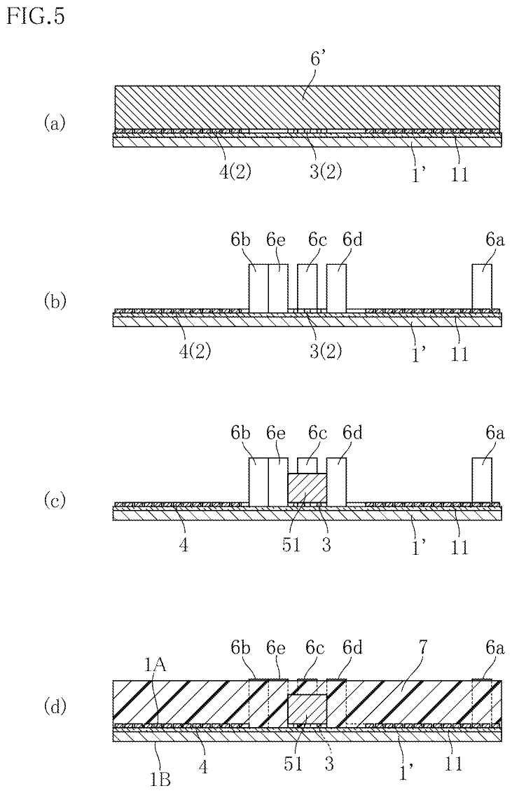

An example of the manufacturing method of the coil module A10 will now be described hereunder, with reference to FIG. 4 and FIG. 5. FIG. 4 and FIG. 5 are cross-sectional views taken along a line III-III in FIG. 2.

Referring first to FIG. 4(a), a substrate material 1′ is prepared. The substrate material 1′ includes the obverse face 1A and the reverse face 1B, oriented in opposite directions to each other in the z-direction. The substrate material 1′ includes a semiconductor material, for example silicon (Si). Although another semiconductor material than the silicon may be employed to form the substrate material 1′, the silicon is advantageous from the viewpoint of the cost. Although the silicon may be either monocrystalline or amorphous, employing the monocrystalline silicon facilitates the processing, by utilizing the crystal lattice plane. The thickness of the substrate material 1′ may be selected as desired, depending on the required size of the coil module A10, required strength, and the cost, but may be, for example, approximately 50 μm. The substrate material 1′ is formed in a size from which a plurality of substrates 1 of the coil module A10 can be taken. In other words, a plurality of coil modules A10 are collectively formed, through the subsequent manufacturing process. However, a method of manufacturing a single piece of the coil module A10 may be adopted.

Proceeding to FIG. 4(b), the insulation layer 11 is formed, for example from an oxide film (SiO₂). To form the insulation layer 11, the entirety of the obverse face 1A of the substrate material 1′ is oxidated. To form the insulation layer 11, a nitride film may be employed, instead of the oxide film. The thermal conductivity of silicon nitride is approximately 20 times as high as that of the silicon oxide, and therefore employing the nitride film improves heat dissipation efficiency. The thickness of the insulation layer 11 is, for example, approximately 1 μm.

Proceeding to FIG. 4(c), a conductor layer 2′ is formed. To be more detailed, for example a Cu layer is formed on the insulation layer 11, by a sputtering method. A barrier seed layer, for example including Ti, may be formed as an underlying layer, before forming the conductor layer 2′.

Proceeding to FIG. 4(d), a mask layer 22 is formed. To form the mask layer 22, for example a photosensitive resist resin may be applied by spraying.

Proceeding to FIG. 4(e), a patterning process is performed on the mask layer 22. The patterning may be performed on the mask layer 22 so as to remove desired portions, through exposure and development based on a photolithography method. The shape of the mask layer 22 obtained through the patterning process corresponds to the shape of the conductor layer 2 (wiring section 3 and coil section 4).

Proceeding to FIG. 4(f), the portion of the conductor layer 2′ exposed from the mask layer 22 is removed. The removal of the conductor layer 2′ is, for example, executed through an etching process. As result, the conductor layer 2 (wiring section 3 and coil section 4) that has been patterned is obtained. Further, the remaining mask layer 22, which is no longer necessary, is also removed through the etching process.

Proceeding to FIG. 5(a), a conductive layer 6′ is formed. Then the conductive layer 6′ is patterned, and the unnecessary portion of the conductive layer 6′ is removed, except for the portions to be formed into the terminal sections 6a to 6h. As result, the terminal sections 6a to 6h are obtained in the desired shape, as shown in FIG. 5(b). During the patterning process of the conductive layer 6′, application of the resist, exposure, development, and etching are performed, as the case may be. Instead of the steps shown in FIG. 5(a) and FIG. 5(b), the resist may be applied first, and the resist may be removed according to the pattern for forming the terminal sections 6a to 6h. Thereafter, Cu layers may be grown at the positions where the resist has been removed, so as to form the terminal sections 6a to 6h.

Proceeding to FIG. 5(c), the driver IC 51 is mounted on the wiring section 3. In this process, the driver IC 51 is bonded to the wiring section 3, via a bump (not shown) provided on the reverse face of the driver IC 51. Employing a solder bump or a gold bump, and utilizing the self-alignment effect based on the surface tension enables the driver IC 51 to be set in position, with high accuracy. The portion of the conductor layer 2 other than the wiring section 3 acts as the coil section 4.

Proceeding to FIG. 5(d), the sealing resin 7 is formed. To form the sealing resin 7, for example, a highly penetrative photocuring resin material is overlaid on the substrate material 1′, and then cured. The sealing resin 7 is formed so as to entirely cover the obverse face 1A of the substrate material 1′, the conductor layer 2 (wiring section 3 and coil section 4), and the driver IC 51. However, the sealing resin 7 is formed to a height that does not reach the respective tip portions of the terminal sections 6a to 6h, so that those tip portions are exposed from the sealing resin 7. Instead, the sealing resin 7 may be formed to a height that exceeds the tip portions of the terminal sections 6a to 6h, and then the sealing resin 7 may be polished, so as to expose the tip portions of the terminal sections 6a to 6h.

Then the substrate material 1′ is cut, for example by a dicer (not shown), which is called a dicing process. Through the dicing process, the coil modules A10, divided into individual pieces as shown in FIG. 1 to FIG. 3, can be obtained. In the case of the illustrated example, the coil modules A10 are each formed in a rectangular parallelepiped shape (rectangular shape in a plan view), as result of the dicing process. Executing the dicing process after the resin encapsulation simplifies the manufacturing process, but the present disclosure is not limited to such a process. For example, the resin encapsulation may be performed after the dicing process of the substrate material 1′. Further, in the case where it is difficult to divide the substrate material 1′ into individual pieces through a sequential dicing process, for example because of a difference in material between the resin portion and the semiconductor portion, the dicing process may be divided into a plurality of steps.

The coil module A10 provides the following advantageous effects.

In the coil module A10, the coil section 4 (which generates the driving force upon being energized) and the driver IC 51 (incorporated with the magnetic detection element for position detection, and configured to supply power to the coil section 4) are integrally packaged, by the substrate 1 and the sealing resin 7. Such a configuration improves the handling efficiency, compared with the case where the coil and the element (driver IC) are separately mounted on the flexible substrate. Accordingly, for example when the coil module A10 is opposed to the magnetic field generator, the coil module A10 can be set at the desired position, with higher accuracy. In addition, patterning the coil section 4 and the wiring section 3 for mounting the driver IC 51 in the same layer leads to improved positioning accuracy inside the coil module A10, between the coil section 4 and the driver IC 51.

In the coil module A10 according to this embodiment, further, the substrate 1, formed of the semiconductor material, is employed as the base for the packaging. When the silicon is employed to form the substrate 1, the linear expansion coefficient is approximately one fifth, the elastic modulus is approximately 40 times as high, and the thermal conductivity is approximately 500 times as high, compared with polyimide which is widely used as the material of the flexible substrate. Therefore, because of using the substrate 1 as the base, the coil module A10 can suppress deformation or distortion, compared with the case where the coil and the element are unified via the flexible substrate. Furthermore, the high thermal conductivity of silicon allows the Joule heat, generated when the coil section 4 is energized, to be efficiently transmitted, which leads to improved heat dissipation performance.

The driver IC 51 is located inside the coil section 4, as viewed in the z-direction. Such an arrangement allows elongate chip elements, such as the driver IC 51, to be efficiently located in the space inside the coil section 4, without leaving a vacant space in vain.

In this embodiment, the plurality of terminal sections 6 (6a to 6h) are each electrically connected to one of the wiring section 3 and the coil section 4. The respective tip portions of the terminal sections 6a to 6h are exposed at the top face 7A of the sealing resin 7. The top face 7A of the sealing resin 7 serves as the mounting surface via which the coil module A10 is mounted, for example, on the flexible substrate in the actuator. The mentioned configuration facilitates the formation of the plurality of terminal sections 6 (6a to 6h) , to be used as the current path to outside. Further, since the substrate 1 is located on the opposite side of the mounting surface, for mounting on the flexible substrate, the coil module A10 is easy to handle.

### <Variation of First Embodiment>

Referring to FIG. 6, a coil module A11, which is a variation of the coil module A10, will be described hereunder. In the coil module A11 is different from the coil module A10, in additionally including a chip capacitor 52. The configuration of the remaining parts, other than the chip capacitor 52, is similar to that of the coil module A10, and therefore detailed description will be skipped. Here, in FIG. 6 and the subsequent drawings, the elements same as or similar to those of the coil module A10 are given the same numeral, and detailed description of such elements will not be repeated.

The chip capacitor 52 serves to stabilize a power source voltage applied to the driver IC 51. The chip capacitor 52 is mounted on the wiring section 3, at a position in the vicinity of the driver IC 51. When an element that handles a large current, like the driver IC 51, is employed, it is desirable to provide the chip capacitor 52 in the vicinity of the element.

The wiring section 3 additionally includes a pattern for connecting the driver IC 51 and the chip capacitor 52, such that, for example, the chip capacitor 52 is connected in parallel between the power source voltage and the ground. Although the respective ends of the chip capacitor 52 are connected to the terminals of the driver IC 51 in FIG. 6, the ends of the chip capacitor 52 may be connected to the power source terminal and the ground terminal, out of the terminal sections 6.

In the coil module A11, both of the driver IC 51, incorporated with the magnetic detection element, and the chip capacitor 52 are mounted, and the driver IC 51 and the chip capacitor 52 are connected via a wire, inside the coil module A11. Therefore, the power source voltage of the driver IC 51 can be stabilized, without the need to provide an external chip capacitor.

### <Other Variations of First Embodiment>

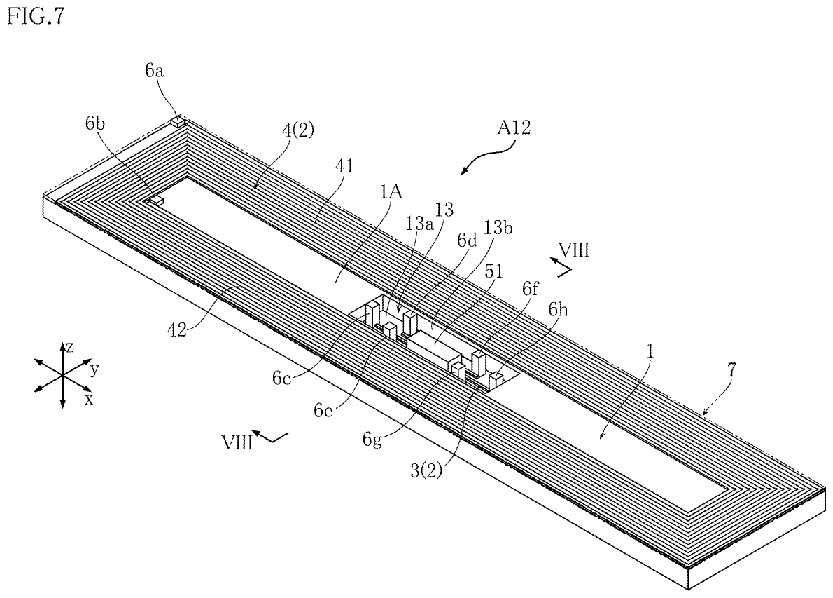

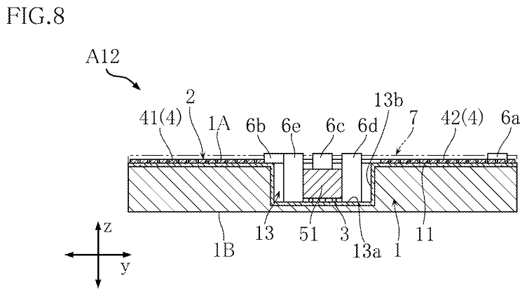

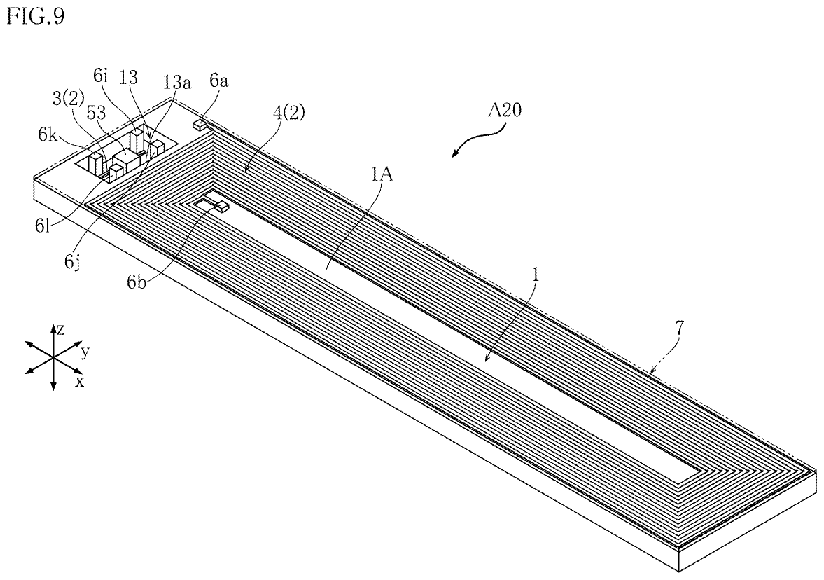

Referring to FIG. 7 and FIG. 8, a coil module A12, which is another variation of the coil module A10, will be described hereunder. FIG. 7 is a perspective view showing a general configuration of the coil module A12. FIG. 8 is an enlarged cross-sectional view taken along a line VIII-VIII in FIG. 7. The coil module A12 is different from the coil module A10 in the configuration of the substrate 1 and the location of the driver IC 51.

In the coil module A12, the substrate 1 is formed in an increased thickness, and a recess 13 is formed in a central region of the substrate 1. The driver IC 51 is accommodated inside the recess 13. recess 13 [symbol] On a bottom face 13a of the recess 13, the wiring section 3 for mounting the driver IC 51 thereon is formed. The wiring section 3 and the coil section 4 are formed in different layers. Therefore, a wiring pattern has to be also formed on a wall face 13b of the recess 13, to connect the wiring section 3 and the coil section 4 inside the coil module A12. In this variation, the wiring section 3 and the coil section 4 are connected via a wiring pattern in the flexible substrate included in the actuator, in which the coil module A12 is to be mounted, instead of forming the wiring on the wall face 13b.

The overall thickness of the substrate 1 may be determined as desired, taking into account the depth of the recess 13 or the height of the driver IC 51, but may be, for example, approximately 700 μm. When the thickness of the substrate 1 is approximately 700 μm, the recess 13 may be formed in a depth of approximately 650 μm. In this case, the thickness of the bottom portion of the recess 13 is approximately 50 μm, which is similar to the thickness of the substrate 1 in the coil module A10. Although the wall face 13b of the recess 13 shown in FIG. 7 and FIG. 8 is generally perpendicular to the bottom face 13a of the recess 13, the present disclosure is not limited to such a configuration. When the angle of the wall face 13b with respect to the bottom face 13a is closer to perpendicular, higher utilization efficiency of the surface of the substrate 1 can be attained. To form the recess 13 with the perpendicular wall face 13b, for example a reactive ion etching (RIE) process may be performed on the substrate 1.

In the coil module A12, the overall thickness of the recess 13 is increased, because of forming the recess 13 in the recess 13. Accordingly, the strength of the coil module A12 as a package is increased. As is apparent from the comparison between the coil module A12 shown in FIG. 8 and the coil module A10 shown in FIG. 3, the overall thickness of the coil module A12 is similar to that of the coil module A10.

When the coil module A12 is used in the actuator, substrate 1 [symbol] the reverse face 1B of the substrate 1 is opposed to the magnetic field generator (permanent magnet). In the coil module A12, the driver IC 51 incorporated with the magnetic detection element is located in the recess 13, and the thickness of the portion of the substrate 1 where the recess 13 is formed is similar to the case of the coil module A10. Such a configuration makes the distance between the driver IC 51, acting as the magnetic detection element, and the magnetic field generator similar to the distance in the coil module A10, thereby preventing a decline in sensitivity in the magnetism detection. Therefore, the coil module A12 possesses a structure advantageous for increasing the strength of the package, without incurring a decline in sensitivity in the magnetism detection.

In the coil module A12, the coil section 4 and the magnetism sensing surface of the driver IC 51 (magnetic detection element) accommodated in the recess 13 are deviated from each other, in the thickness direction (z-direction). When the magnetic field, generated by energizing the coil section 4, is incident on the magnetic detection element, such magnetic field constitutes a noise, and therefore an erroneous signal different from the normal position detection signal is outputted. A vertical component of the magnetic field generated in the coil section 4 (vertical component of the magnetic field incident on the magnetic detection element) tends to become largest at the same position (height) as the coil section 4, in the thickness direction (z-direction) thereof. Locating the coil section 4 and the magnetism sensing surface of the magnetic detection element at deviated positions in the thickness direction (z-direction) of the coil section 4, as described above, reduces the impact of the magnetic field noise from the coil section 4.

### Second Embodiment

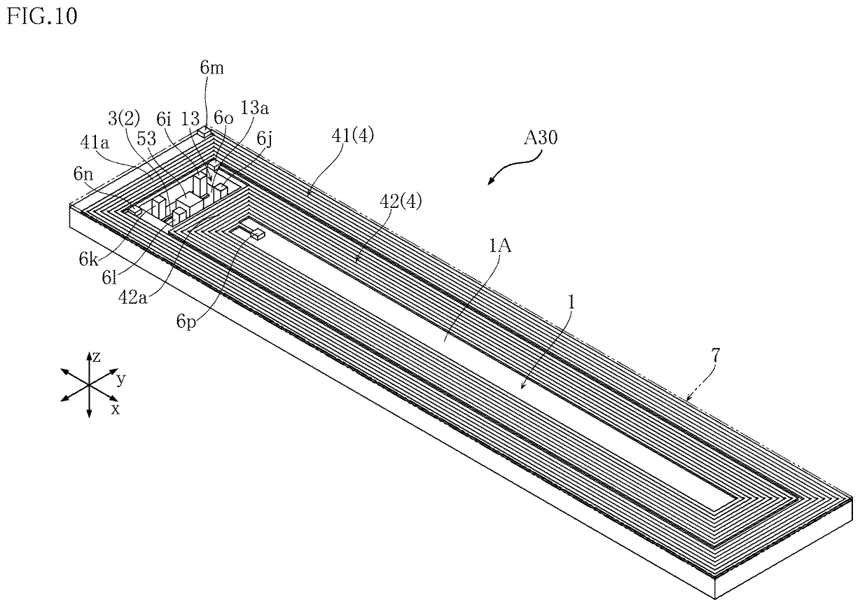

Referring to FIG. 9, a coil module A20 according to a second embodiment will be described hereunder. The coil module A20 is different from the coil module A10 and the variations thereof, mainly in the configuration and location of the elements.

The coil section 4 is formed in a similar pattern to that of the coil module A10. On the other hand, the coil section 4 is formed in the region of the substrate 1 other than an end portion (upper left side in FIG. 9) in the longitudinal direction (x-direction). In this embodiment, a Hall element 53 is located outside of the coil section 4, as viewed in the z-direction. In this embodiment, the recess 13 is formed in the end portion of the substrate 1 (upper left side in FIG. 9) in the longitudinal direction. The Hall element 53 is accommodated in the recess 13.

In this embodiment, the recess 13 is formed as a groove extending in the width direction of the substrate 1 (y-direction). Accordingly, a sufficient size of the recess 13 in the longitudinal direction (y-direction) may be unable to be secured. In this embodiment, therefore, the Hall element 53 is employed as the magnetic detection element. Provided that a sufficient space can be secured in the recess 13, the driver IC 51 incorporated with the magnetic detection element may be mounted, instead of the Hall element 53. In addition, although the Hall element 53 is located in the recess 13, a structure without the recess may be adopted.

The wiring section 3 is provided on the bottom face 13a of the recess 13. The Hall element 53 is mounted on the wiring section 3. The wiring sections 3 includes four wiring elements (partially shown), to the respective ends of which terminal sections 6i to 6l are connected. The other ends of the wiring section 3 are connected to the terminal of the Hall element 53. Out of the terminal sections 6i to 6l, two are connected to bias-side terminals of the Hall element 53, and the other two are connected to output terminals of the Hall element 53. The driver that supplies a bias current to the Hall element 53 and supplies a driving current to the coil section 4 is connected to outside of the coil module A20. The coil module A20 and the driver may be connected, for example, via a wiring pattern in the flexible substrate included in the actuator.

It is for the purpose of suppressing the magnetic field, generated when the coil section 4 is energized, from leaking into the magnetic detection element, that the Hall element 53 (magnetic detection element) is located outside the windings of the coil section 4, as in the coil module A20. The magnetic field, generated by energizing the coil section 4 of the rectangular shape, tends to become more intense inside the windings of the coil section 4, because the magnetic flux is concentrated from the lines of the four sides. In contrast, in the outer region of the windings of the coil section 4, the magnetic flux from the lines of only one side of the coil section 4 is predominant, and therefore the amount of the magnetic flux is smaller, compared with the inner region of the windings of the coil section 4. Thus, the configuration of the coil module A20 suppresses the magnetic field noise from the coil section 4 from being incident on the Hall element 53.

### Third Embodiment

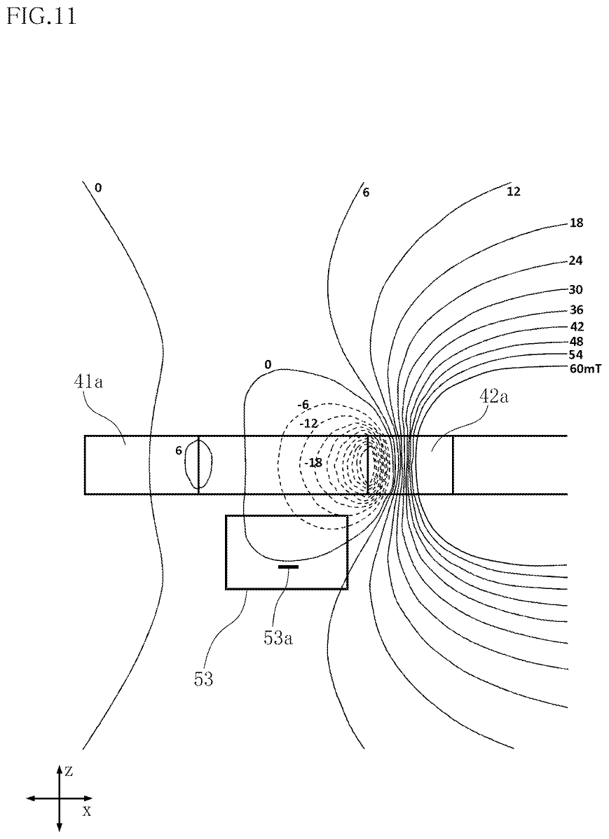

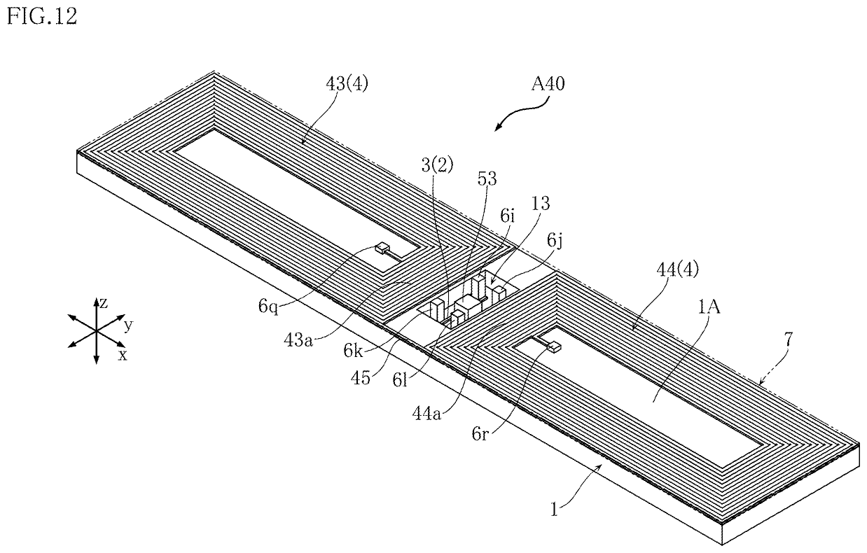

Referring to FIG. 10 and FIG. 11, a coil module A30 according to a third embodiment will be described hereunder. FIG. 10 is a perspective view showing a general configuration of the coil module A30. FIG. 11 is a schematic drawing showing distribution of magnetic flux density resultant from coil energization, around a magnetic detection element. The coil module A30 is different from the coil module A20, mainly in the configuration of the coil section 4 and the location of the Hall element 53.

In this embodiment, the coil section 4 has a double structure including an outer coil 41 and an inner coil 42. The outer coil 41 is formed close to the peripheral edge of the substrate 1. The inner coil 42 is formed inside the windings of the outer coil 41, as viewed in the z-direction (thickness direction of the substrate 1). The Hall element 53 is located inside the windings of the outer coil 41, and outside the windings of the inner coil 42, as viewed in the z-direction.

In this embodiment, the recess 13 is formed in one end portion of the substrate 1 (upper left side in FIG. 10) in the longitudinal direction, and the Hall element 53 is accommodated in the recess 13. Provided that a sufficient space can be secured in the recess 13, the driver IC 51 incorporated with the magnetic detection element may be mounted, instead of the Hall element 53. In addition, although the Hall element 53 is located in the recess 13, a structure without the recess may be adopted.

Four wiring sections 3 are formed on the bottom face 13a of the recess 13, and the Hall element 53 is mounted on the wiring sections 3. The configuration of the wiring section 3 and the terminal sections 6i to 6j each connected to the end of the wiring section 3 is similar to that of the coil module A20.

In this embodiment, a plurality of terminal sections 6m, 6n, 6o, and 6p, each connected to the coil section 4, are provided. To be more detailed, the terminal sections 6m and 6n are connected to the respective ends of the outer coil 41. The terminal sections 6o and 6p are connected to the respective ends of the inner coil 42. The four terminal sections 6i to 6l connected to the Hall element 53, and the four terminal sections 6m to 6p connected to the coil section 4 are connected to the flexible substrate of the actuator. The outer coil 41 and the inner coil 42 are connected in series to each other, for example via the wiring pattern in the flexible substrate. However, the present disclosure is not limited to such a configuration, but the connection structure of the outer coil 41 and the inner coil 42 may be selected as desired. When it is intended to apply different amounts of current to the outer coil 41 and the inner coil 42, the outer coil 41 and the inner coil 42 may be connected in parallel.

It is for the purpose of suppressing the magnetic field, generated when the coil section 4 is energized, from being incident on the magnetic detection element and constituting a noise, that the Hall element 53 (magnetic detection element) is located inside the windings of the outer coil 41, and outside the windings of the inner coil 42. When the current is applied in the same direction to the double structure of the outer coil 41 and the inner coil 42, each formed in the helical shape, the magnetic fields of opposite directions are incident on the Hall element 53 (magnetic detection element) located as FIG. 10, from the outer coil 41 and the inner coil 42. Accordingly, the magnetic fields incident on the Hall element 53 can be set off, so as to reduce the noise, by adjusting the number of turns of the outer coil 41 and the inner coil 42, or adjusting the current to be applied to each of the coils 41 and 42, such that the intensity of each of the magnetic fields becomes generally the same.

FIG. 11 schematically illustrates a distribution of the magnetic flux density, around the central cross-section in the vicinity of the Hall element 53 (magnetic detection element), resultant from the coil energization. FIG. 11 illustrates the cross-sections of a side 41a of the outer coil 41 located on the upper left side of the Hall element 53 in FIG. 10, and of a side 42a of the inner coil 42 located on the lower right side of the Hall element 53. The Hall element 53 is located inside the recess 13 of the substrate 1. Accordingly, the Hall element 53 is mounted at the position slightly deviated from the coil section 4, in the thickness direction thereof (z-direction). For such reason, a magnetism sensing surface 53a of the Hall element 53 is located at the position shown in FIG. 11.

The curves in FIG. 11 each represent a contour line along which the magnetic flux density is equal, and the numeral accompanying the contour line represents the magnetic flux density of the contour line, in a unit of milli Tesla (mT). The plus and minus symbols attached to the numeral indicate that the magnetic fluxes flow in opposite directions. In this example, further, the outer coil 41 and the inner coil 42 are given different number of turns, so that the magnetic flux density becomes zero in the vicinity of the middle point between the side 41a of the outer coil 41 and the side 42a of the inner coil 42. Here, different amounts of current may be applied to the respective coils, instead of giving different number of turns. While the magnetic fluxes from the outer coil 41 are collectively concentrated from three directions, the magnetic flux from the inner coil 42 imposes an impact, mainly from one direction. Accordingly, the magnetic flux from the outer coil 41 imposes a larger impact. Therefore, the number of turns of the outer coil 41, or the amount of current applied thereto, may be relatively reduced, to create the state where the magnetic flux density is zero, in the vicinity of the middle point between the side 41a of the outer coil 41 and the side 42a of the inner coil 42.

Thus, the configuration according to this embodiment can minimize the magnetic flux density on the magnetism sensing surface 53a of the Hall element 53, resultant from the current application to the coil section 4, thereby reducing the noise to the Hall element 53.

### Fourth Embodiment

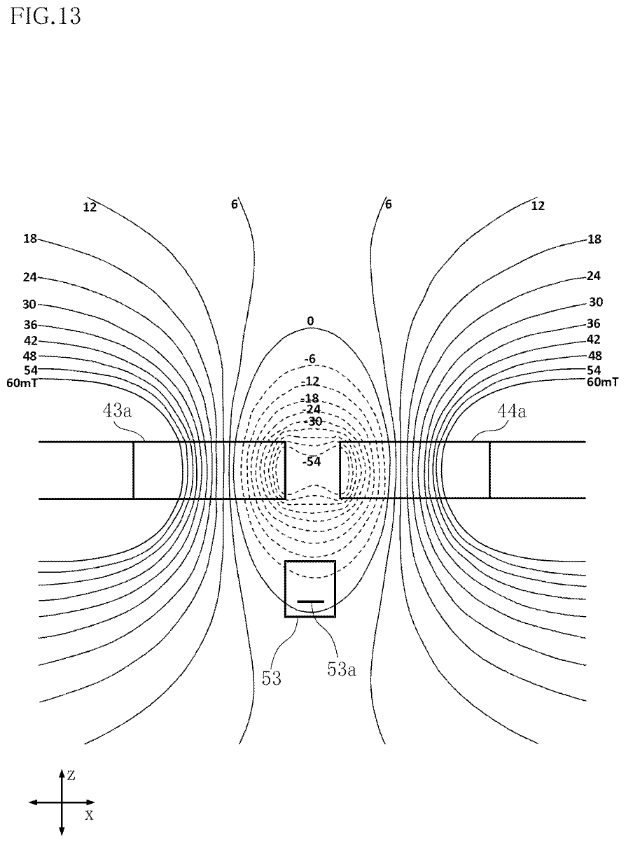

Referring to FIG. 12 and FIG. 13, a coil module A40 according to a fourth embodiment will be described hereunder. FIG. 12 is a perspective view showing a general configuration of the coil module A40. FIG. 13 is a schematic drawing showing the distribution of the magnetic flux density resultant from the coil energization, around the magnetic detection element. The coil module A40 is different from the coil module A30, mainly in the configuration of the coil section 4 and the location of the Hall element 53.

In this embodiment, the coil section 4 includes a first coil 43 located on the left in FIG. 12, and a second coil 44 located on the right. The first coil 43 and the second coil 44 are located side by side, as viewed in the z-direction (thickness direction of the substrate 1). The Hall element 53 is located between the first coil 43 and the second coil 44, as viewed in the z-direction.

In this embodiment, the recess 13 is formed at the center of the substrate 1 in the longitudinal direction (x-direction), and the Hall element 53 is accommodated in the recess 13. Provided that a sufficient space can be secured in the recess 13, the driver IC 51 incorporated with the magnetic detection element may be mounted, instead of the Hall element 53. Although the Hall element 53 is located in the recess 13, a structure without the recess 13 may be adopted. However, as will be subsequently described, forming the recess 13, and locating the magnetism sensing surface 53a of the Hall element 53 at the position deviated from the coil section 4 in the thickness direction thereof (z-direction), is advantageous in reducing the density of the magnetic flux, incident on the magnetism sensing surface 53a from the coil.

Four wiring sections 3 are formed on the bottom face 13a of the recess 13, and the Hall element 53 is mounted on the wiring sections 3. The configuration of the wiring section 3 and the terminal sections 6i to 6j each connected to the end of the wiring section 3 is similar to that of the coil modules A20 and A30.

In this embodiment, the first coil 43 and the second coil 44 are connected in series to each other, via a connecting portion 45 located therebetween. The coil module A40 includes terminal sections 6q and 6r connected to the coil section 4. The terminal section 6q is connected to an end of the first coil 43. The terminal section 6r is connected to an end of the second coil 44. The four terminal sections 6i to 6l connected to the Hall element 53, and the two terminal sections 6q and 6r connected to the coil section 4, are connected to the flexible substrate of the actuator.

It is for the purpose of suppressing the magnetic field, generated when the coil section 4 is energized, from being incident on the magnetic detection element and constituting a noise, that the Hall element 53 (magnetic detection element) is located between the first coil 43 and the second coil 44. As shown in FIG. 13, a point where the magnetic flux density component becomes zero exists, at a position on the middle line between the first coil 43 and the second coil 44, and slightly deviated from the coil section 4 in the thickness direction thereof (z-direction). Therefore, locating the magnetism sensing surface 53a of the Hall element 53 in the vicinity of the point where the magnetic flux density component becomes zero, reduces the density of the magnetic flux incident on the Hall element 53, thereby reducing the noise affecting the Hall element 53.

The above will be described in further detail, with reference to FIG. 13. FIG. 13 schematically illustrates a distribution of the magnetic flux density, around the central cross-section in the vicinity of the Hall element 53 (magnetic detection element), resultant from the coil energization. FIG. 13 illustrates the cross-sections of a side 43a of the first coil 43 located on the upper left side of the Hall element 53 in FIG. 12, and of a side 44a of the second coil 44 located on the lower right side of the Hall element 53. The Hall element 53 is located inside the recess 13 of the substrate 1. Accordingly, the Hall element 53 is mounted at the position slightly deviated from the coil section 4, in the thickness direction thereof (z-direction). For such reason, the magnetism sensing surface 53a of the Hall element 53 is located at the position shown in FIG. 13.

The curves in FIG. 13 each represent a contour line along which the magnetic flux density is equal, and the numeral accompanying the contour line represents the magnetic flux density of the contour line, in the unit of milli Tesla (mT). The plus and minus symbols attached to the numeral indicate that the magnetic fluxes flow in opposite directions. As shown in FIG. 13, the magnetic flux density becomes relatively high, at the position along the middle line between the two coils (first coil 43 and second coil 44), corresponding to the coil section 4 in the thickness direction thereof (z-direction). However, at the position deviated from the coil section 4 in the thickness direction thereof, a point where the magnetic flux density becomes substantially zero exists. Therefore, locating the Hall element 53 such that the magnetism sensing surface 53a of the Hall element 53 (magnetic detection element) is positioned in the vicinity of the position where the magnetic flux density component becomes zero, prevents the intrusion of the noise into the Hall element 53.

Thus, the configuration according to this embodiment can minimize the magnetic flux density on the magnetism sensing surface 53a of the Hall element 53, resultant from the current application to the coil section 4, thereby reducing the noise affecting the Hall element 53.

### Fifth Embodiment

Referring to FIG. 14, a coil module A50 according to a fifth embodiment will be described hereunder. The coil module A50 is different from the coil module A10, mainly in the configuration of the coil section 4.

In this embodiment, the coil section 4 includes a plurality of layers, stacked with an interval therebetween. To be more detailed, the coil section 4 includes a lower coil 461 and an upper coil 462. The lower coil 461 is formed on the substrate 1, with the insulation layer 11 interposed therebetween. The upper coil 462 is spaced from the lower coil 461, in the thickness direction of the substrate 1 (z-direction). To form such a coil section 4, first the lower coil 461 is formed on the substrate material 1′, and an intermediate insulation layer (not shown) is formed on the surface of the first the lower coil 461. Thereafter, the upper coil 462 is formed on the intermediate insulation layer.

In this embodiment, a plurality of terminal sections 6s, 6t, 6u, and 6v, each connected to the coil section 4, are provided. To be more detailed, the terminal sections 6s and 6v are connected to the respective ends of the lower coil 461. The terminal sections 6t and 6u are connected to the respective ends of the upper coil 462. The terminal sections 6s and 6v penetrate through the intermediate insulation layer, and protrude to the upper side. The wiring section 3, on which the driver IC 51 (element) is to be mounted, is formed in the same layer in which the lower coil 461 is formed. In this embodiment, six wiring sections 3 are provided, to the respective ends of which the terminal sections 6c to 6h are connected. The other ends of the wiring sections 3 are connected to the terminals of the driver IC 51.

The sealing resin 7 covers the major part of the terminal sections 6c to 6h and 6s to 6v, except for the tip portion thereof. The tip portion of each of the terminal sections 6c to 6h and 6s to 6v is exposed on the top face of the sealing resin 7. In the sealing resin 7, the face where the terminal sections 6c to 6h and 6s to 6v are exposed serves as the mounting surface via which the coil module A50 is mounted, for example, on the flexible substrate in the actuator. The connection between the terminal sections may be made via the wiring pattern in the flexible substrate, depending on the purpose of the connection.

Since the coil section 4 includes the plurality of layers (lower coil 461 and upper coil 462) stacked on each other in this embodiment, the total number of turns of the coil section 4 can be increased. Therefore, when the coil module A50 is incorporated in the actuator, the driving force can be increased.

### Sixth Embodiment

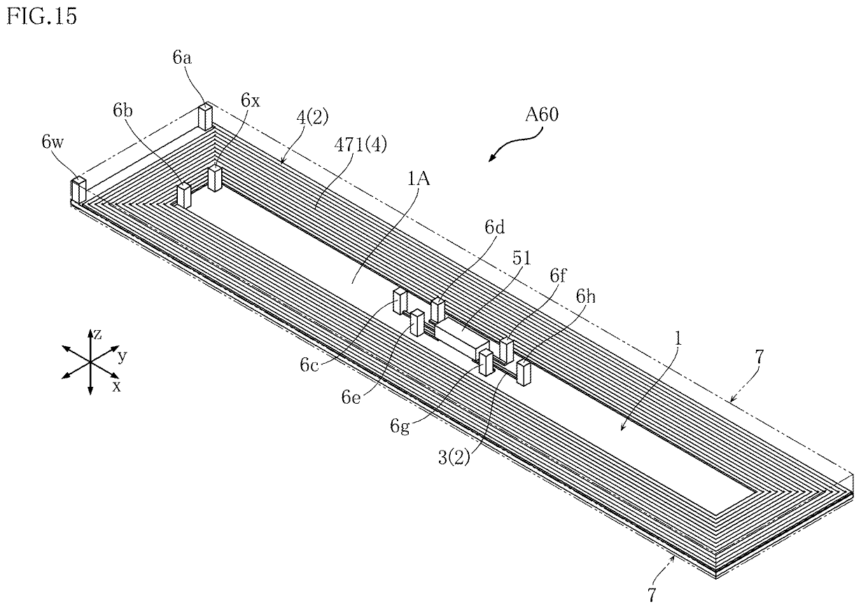

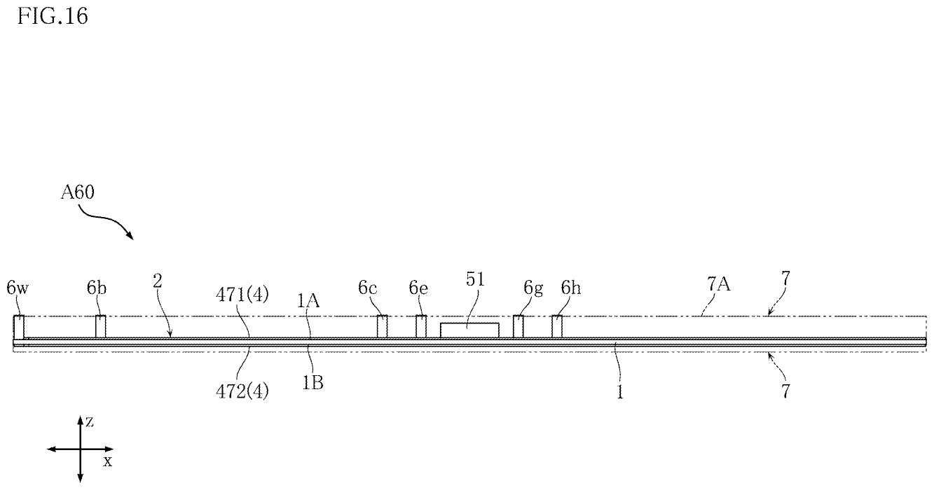

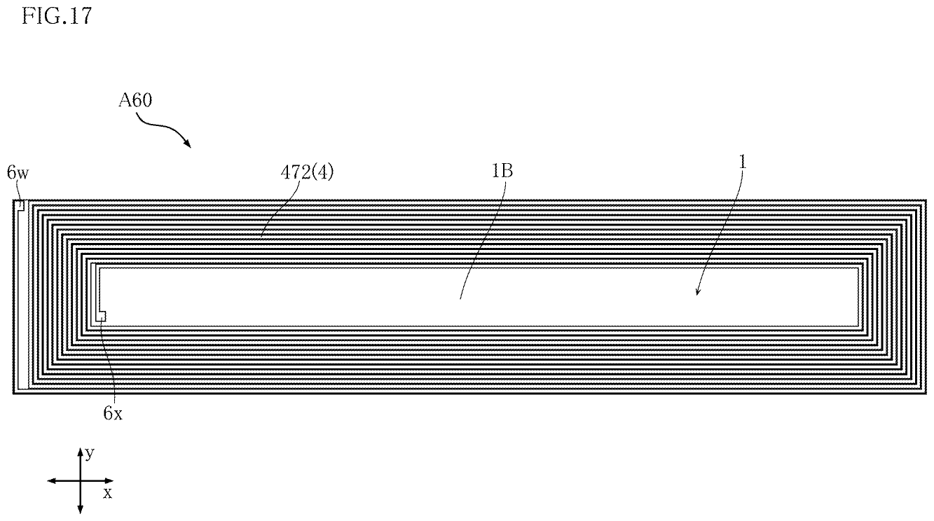

Referring to FIG. 15 to FIG. 17, a coil module A60 according to a sixth embodiment will be described hereunder. FIG. 15 is a perspective view showing a general configuration of the coil module A60. FIG. 16 is a front view of the coil module A60. FIG. 17 is a bottom view of the coil module A60. In FIG. 17, the sealing resin 7 is not shown. The coil module A60 is different from the coil module A10, mainly in the configuration of the coil section 4.

In this embodiment, the coil section 4 is formed on both faces of the substrate 1, in the thickness direction (z-direction). More specifically, the coil section 4 includes an obverse face coil 471 and a reverse face coil 472. The obverse face coil 471 is formed on the obverse face 1A of the substrate 1. The reverse face coil 472 is formed on the reverse face 1B of the substrate 1. At the respective ends of the reverse face coil 472, terminal sections 6w and 6x are provided. The terminal sections 6w and 6x each penetrate through the substrate 1, and protrude toward the top face 7A of the sealing resin 7.

The sealing resin 7 covers the major part of the terminal sections 6a to 6h, 6w, and 6x, except for the tip portion thereof. In this embodiment, the sealing resin 7 is also formed on the reverse face 1B of the substrate 1, so as to cover the reverse face coil 472. The respective tip portions of the terminal sections 6a to 6h, 6w, and 6x are exposed on the top face 7A of the sealing resin 7. The top face 7A of the sealing resin 7 serves as the mounting surface, for example to the flexible substrate of the actuator. The connection between the terminal sections may be made via the wiring pattern in the flexible substrate, depending on the purpose of the connection.

According to this embodiment, the coil section 4 can be provided in two layers, because of utilizing the both faces of substrate 1, and therefore the total number of turns of the coil section 4 can be increased. Accordingly, when the coil module A60 is incorporated in the actuator, the driving force can be increased.

### Seventh Embodiment

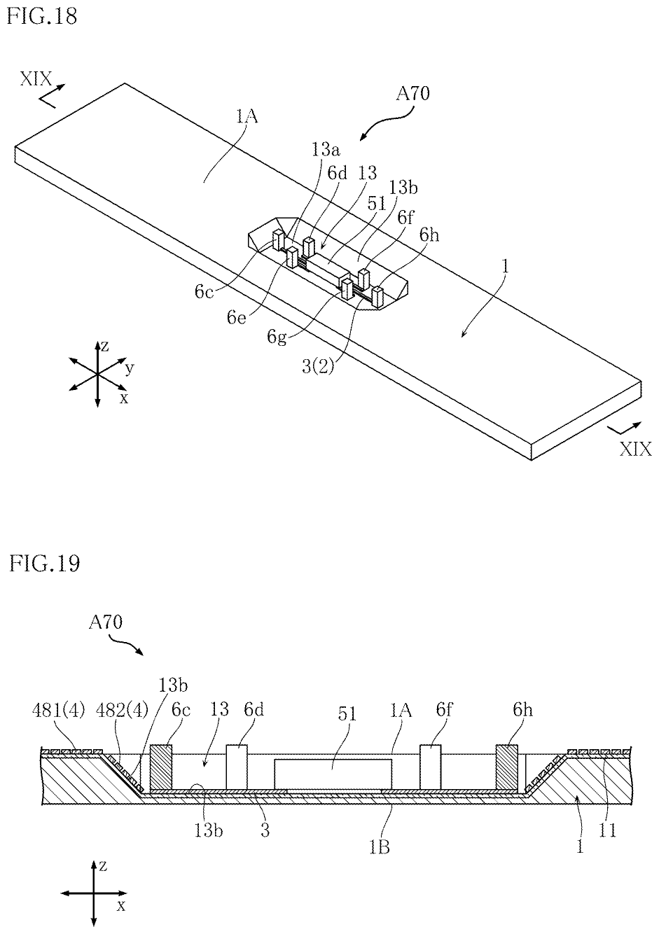

Referring to FIG. 18 and FIG. 19, a coil module A70 according to a seventh embodiment will be described hereunder. FIG. 18 is a perspective view showing a general configuration of the coil module A70. FIG. 19 is an enlarged cross-sectional view taken along a line XIX-XIX in FIG. 18. The coil section 4 and the sealing resin 7 are not shown in FIG. 18, and the sealing resin 7 is not shown in FIG. 19. The coil module A70 is different from the coil module A12, mainly in the configuration of the substrate 1 and the coil section 4.

In this embodiment, the recess 13 is formed in the central region of the substrate 1. Although the recess 13 of the coil module A12 (see FIG. 7 and FIG. 8) includes the vertical wall face 13b, the recess 13 according to this embodiment includes the inclined wall face 13b. The recess 13 having the inclined wall face 13b can be formed, for example, by an anisotropic etching process using KOH. When monocrystalline silicon is employed as the semiconductor material for the substrate 1, and the crystal orientation of the obverse face 1A is (100) [Miller index], the inclination angle of the wall face 13b with respect to the bottom face 13a becomes approximately 55 degrees.

In this embodiment, as shown in FIG. 19, the coil section 4 is formed on both of the obverse face 1A of the substrate 1 and the wall face 13b. More specifically, the coil section 4 includes a flat coil 481 and an inclined coil 482. The flat coil 481 is formed on the obverse face 1A of the substrate 1. The inclined coil 482 is formed on the wall face 13b of the substrate 1. The flat coil 481 and the inclined coil 482 are connected to each other, in the coil module A70.

According to this embodiment, the inclined coil 482 is formed on the wall face 13b of the substrate 1, and therefore the surface of the substrate 1 can be effectively utilized as the region to form the coil section 4. In addition, the total number of turns of the coil section 4 can be increased, compared with the case where the coil section 4 is formed only on the obverse face 1A of the substrate 1. Accordingly, when the coil module A70 is incorporated in the actuator, the driving force can be increased.

### Eighth Embodiment

Referring to FIG. 20 and FIG. 21, a coil module A80 according to an eighth embodiment will be described hereunder. FIG. 20 is a perspective view showing a general configuration of the coil module A80. FIG. 21 is an enlarged cross-sectional view taken along a line XXI-XXI in FIG. 20. The coil module A80 is different from the coil module A10, mainly in further including an additional coil 40.

In this embodiment, the additional coil 40 is formed on the coil section 4. As viewed in the z-direction, the additional coil 40 extends along the coil section 4, and overlaps therewith. As shown in FIG. 21, the thickness of the additional coil 40 (size in the z-direction) is larger than that of the coil section 4. As an example, the additional coil 40 may be at least twice as thick as the coil section 4, or may be seven to eight times as thick as the coil section 4, as the example shown in FIG. 21. On the other hand, it is preferable that the additional coil 40 is made lower as a whole than the terminal sections 6a, 6b, and so forth, so as not to be exposed from the sealing resin 7. In this case, as shown in FIG. 21, the upper edge of the additional coil 40 is located at a position lower than the upper end of the terminal sections 6a, 6b, and so forth (i.e., position closer to the substrate 1). The additional coil 40 is, for example, formed of Cu, through an electrolytic plaiting process utilizing the coil section 4.

According to this embodiment, the overall thickness of the coil, including the coil section 4 and the additional coil 40, can be efficiently increased, which contributes to reducing the resistance and suppressing heat generation.

### Ninth Embodiment

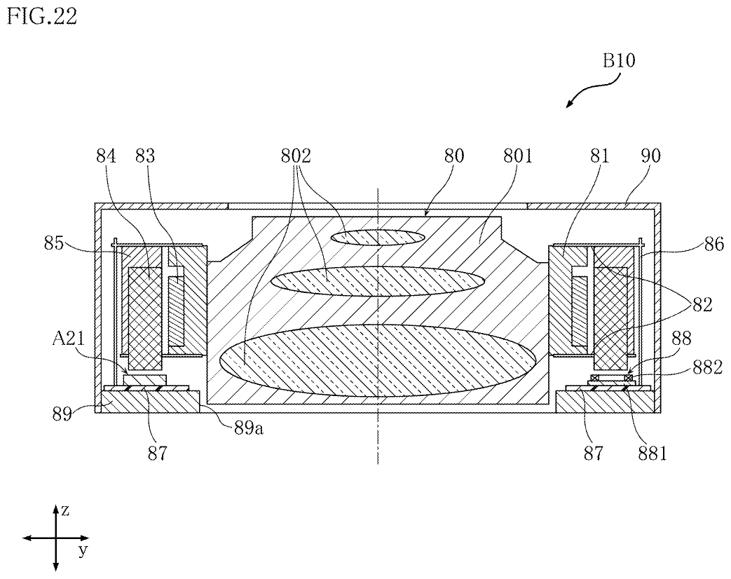

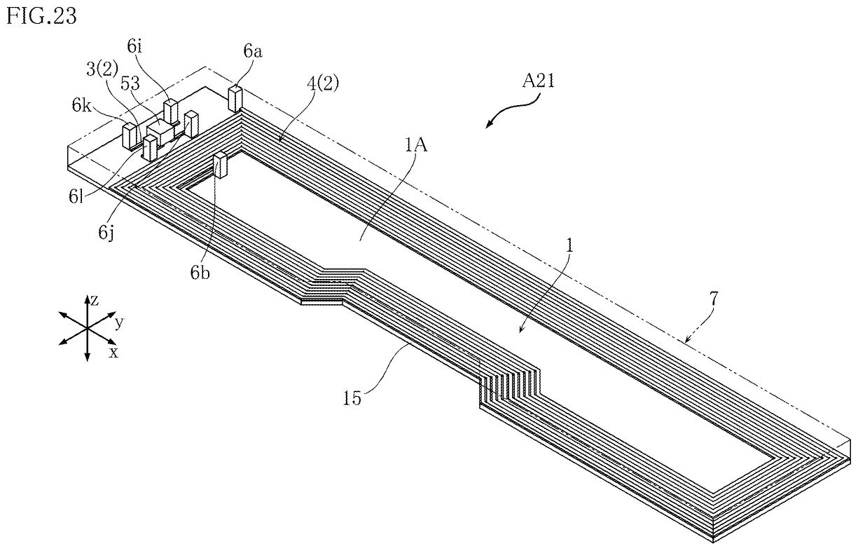

Referring to FIG. 22 to FIG. 24, an example where the coil module is incorporated in the actuator will be described hereunder. FIG. 22 is a central cross-sectional view showing an actuator B10 according to the ninth embodiment. FIG. 23 is a perspective view showing a general configuration of a coil module A21 appropriate for use in the actuator B10 shown in FIG. 22. FIG. 24 is a plan view showing a structure including a coil component without an element, in addition to the coil module A21 shown in FIG. 23, which is appropriate for use in the actuator B10 shown in FIG. 22.

The actuator B10 shown in FIG. 22 is, for example, used to drive the lens in a camera module. However, the present disclosure is not limited thereto, but the actuator B10 may be used to drive different parts for different purposes. In this embodiment, it will be assumed that the actuator B10 is intended for use in the camera module, and capable of supporting, in particular, an autofocus (AF) function and an optical image stabilization (OIS) function. An imaging lens 80 in the camera module includes a lens barrel 801, and a plurality of lens elements 802. Although three lens elements 802 are illustrated, the number of lens elements 802 is not limited thereto.

The actuator B10 includes the coil module A21, a lens holder 81, a leaf spring 82, an AF coil 83, a permanent magnet 84, a magnet holder 85, a suspension wire 86, a flexible substrate 87, a coil component 88, a base 89, and a cover 90.

The lens holder 81 retains the imaging lens 80. The lens holder 81 and the lens barrel 801 are bonded together, after height adjustment of the imaging lens 80. The AF coil 83 is wound around the outer circumferential surface of the lens holder 81. The permanent magnet 84 is located so as to oppose the AF coil 83. The permanent magnet 84 is fixed to the magnet holder 85. When the AF coil 83 is energized, electromagnetic force (Lorentz force) is generated between the AF coil 83 and the permanent magnet 84, so that the AF coil 83 is subjected to the force in the direction along the optical axis. The lens holder 81 supported by an upper and a lower leaf spring 82, so as to move relative to the magnet holder 85 in the direction along the optical axis. The imaging lens 80, the lens holder 81, and the AF coil 83 constitute an AF movable section.

The flexible substrate 87 is bonded to the base 89. The cover 90 covers the internal components of the actuator B10, and includes an opening formed in the top face for securing the optical path. The base 89 and the cover 90 are integrally combined. The permanent magnet 84 is included in an OIS movable section, it is preferable that the cover 90 is formed of a non-magnetic metal (e.g., copper-based alloy such as nickel silver). The base 89 includes an opening 89a formed in the central region, in which a part of the imaging lens 80 is located.

On the flexible substrate 87, the coil module A21 and the coil component 88 are located so as to oppose the permanent magnet 84. The coil module A21 includes the Hall element 53 acting as the magnetic detection element, and the coil section 4 acting as an OIS coil, which are integrally packaged. The coil component 88 is spaced from the in the y-direction, and located so as to constitute a pair with the coil module A21, across the opening 89a of the base 89. When the coil module A21 and the coil component 88 shown in FIG. 22 are for position detection in the y-direction and driving, another coil module and another coil component for position detection in the x-direction (perpendicular to the sheet of FIG. 22) are respectively located at non-illustrated positions.

Although the coil module A21 shown in FIG. 23 is configured similarly to the coil module A20, the substrate 1 of the coil module A21 is without the recess 13. On the other hand, a cutout 15 is formed in the substrate 1. Depending on the design of the actuator B10, the cutout 15 of a trapezoidal shape is formed to properly secure a gap from the imaging lens 80. In the coil module A21, the coil section 4 is formed, for example, along the cutout 15.

The coil component 88 shown in FIG. 22 and FIG. 24 may have the same structure as the coil module A21, but without the Hall element 53 and the terminal sections for the element. The coil component 88 is, for example, formed by patterning an OIS coil 882 on a coil substrate 881 formed of silicon or the like. When a cutout 883 of a trapezoidal shape, like that of the substrate 1 of the coil module A21, is formed in the coil substrate 881 of the coil component 88 as shown in FIG. 24, the coil component 88 can be symmetrically located to the coil module A21, across the opening 89a of the base 89. Locating thus the coil module A21 and the coil component 88, such that the trapezoidal cutouts 15 and 883 are opposed to each other, enables the space including the region close to the opening 89a of the base 89 to be effectively utilized.

Here, it is difficult to form the trapezoidal cutout 15 through a dicing process. However, the coil module A21 including the trapezoidal cutout 15 can be obtained, through forming a trapezoidal hole in the semiconductor substrate of a bare state, by etching or the like, performing the coil formation, element mounting, and resin encapsulation on the region on the substrate other than the hole, and then dicing the coil module. In this case, when the structure on the substrate is patterned such that the trapezoidal cutouts 15 of adjacent coil modules A21 oppose each other, the two cutouts 15 can be taken from one hole, and therefore the manufacturing process can be simplified.

As shown in FIG. 22, a part of the leaf spring 82 on the upper side protrudes to the outer side of the magnet holder 85, and the protruding portion is connected to the upper end of the suspension wire 86. The lower end of the suspension wire 86 is connected to the flexible substrate 87, and the terminal of the AF coil 83 is electrically connected to the flexible substrate 87, via the leaf spring 82 (upper side) and the suspension wire 86. The suspension wire 86 supports the magnet holder 85 so as to move in the direction perpendicular to the optical axis. The magnet holder 85, the permanent magnet 84, and the AF movable section constitute the OIS movable section.

As described above, the coil module A21 and the coil component 88 are each located on the flexible substrate 87, so as to oppose the permanent magnet 84. When current is supplied to the coil section 4 of the coil module A21 and the OIS coil 882 of the coil component 88, electromagnetic force (Lorentz force) is generated between each coil and the corresponding permanent magnet 84, so that the coil section 4 and the OIS coil 882 are subjected to the force in the direction perpendicular to the optical axis. The coil module A21 including the coil section 4, and the coil component 88 including the OIS coil 882 are fixed to the flexible substrate 87. Accordingly, the permanent magnet 84 is subjected to a force in the direction perpendicular to the optical axis, owing to the reaction of the Lorentz force. Then, because of the mentioned configuration of the OIS movable section, the permanent magnet 84 is displaced in the direction perpendicular to the optical axis. The coil module A21 includes the Hall element 53. The Hall element 53 detects a change of the magnetic flux (component in the z-direction) resultant from the displacement of the permanent magnet 84, and thus the position detection can be performed.

To control the optical image stabilization (OIS), for example a feedback control is performed as described hereunder. First, the angle of the camera shake is detected by a non-illustrated gyro sensor (angular velocity sensor), and an amount of displacement, by which the OIS movable section (permanent magnet 84, magnet holder 85, and imaging lens 80 supported thereby) is to be displaced in the direction perpendicular to the optical axis (target amount of displacement) is calculated. Then a current corresponding to the target amount of displacement of the OIS movable section is supplied to the coil section 4 and the OIS coil 882. Then, an actual amount of displacement of the OIS movable section (measured amount of displacement) is detected, according to the detection signal from the Hall element 53. When the measured amount of displacement and the target amount of displacement discord with each other, the input current to the coil section 4 and the OIS coil 882 is adjusted.

In the actuator B10 according to this embodiment, the permanent magnet 84 performs three functions, namely the AF driving, the OIS driving, and the position detection for the OIS. Utilizing thus the permanent magnet 84 for both driving and position detection contributes to reducing the number of parts of the actuator B10.

As may be apparent from the foregoing description, the coil module according to the present disclosure is appropriate for use in the actuator of the camera module or the like. The coil module according to the present disclosure is easy to handle in the mounting process for use in the actuator, and capable of maintaining the positional relation between the coil section and the element with high accuracy. Further, because of the high thermal conductivity of the substrate formed of the semiconductor material, the coil module provides high dissipation efficiency of the Joule heat generated in the coil section.

Although specific embodiments of the present disclosure have been described as above, the present disclosure is not limited to those embodiments, but may be modified in various manners without departing from the scope of the present disclosure. The specific configuration of the coil module and the actuator according to the present disclosure may be modified as desired.

The present disclosure encompasses the configurations according to the following clauses.

Clause 1.

A coil module including:

a substrate including a semiconductor material; a conductor layer formed on the substrate, and including a wiring section, and a coil section of a helical shape;

at least one element mounted on the wiring section; and

a sealing resin covering an obverse surface of the substrate, the conductor layer, and the at least one element.

Clause 2.

The coil module according to clause 1, in which the at least one element includes a magnetic detection element.

Clause 3.

The coil module according to clause 2, in which the at least one element includes a driver IC, and the magnetic detection element is mounted inside the driver IC.

Clause 4.

The coil module according to clause 3, in which the driver IC and the coil section are electrically connected to each other, via the wiring section.

Clause 5.

The coil module according to any one of clauses 2 to 4, in which the at least one element includes a chip capacitor.

Clause 6.

The coil module according to any one of clauses 2 to 5, in which the at least one element is located inside the coil section, as viewed in a thickness direction of the substrate.

Clause 7.

The coil module according to any one of clauses 2 to 5, in which the at least one element is located outside the coil section, as viewed in a thickness direction of the substrate.

Clause 8.

The coil module according to any one of clauses 2 to 5, in which the coil section includes an outer coil, and an inner coil located inside the outer coil as viewed in a thickness direction of the substrate, and

the at least one element is located inside the outer coil, and outside the inner coil, as viewed in the thickness direction of the substrate the substrate.

Clause 9.

The coil module according to any one of clauses 2 to 5, in which the coil section includes a first coil and a second coil connected in series to each other, and located side by side as viewed in a thickness direction of the substrate, and

the at least one element is located between the first coil and the second coil, as viewed in the thickness direction of the substrate.

Clause 10.

The coil module according to any one of clauses 2 to 9, in which the substrate is formed with a recess, and

the at least one element is accommodated in the recess.

Clause 11.

The coil module according to any one of clauses 1 to 10, in which the coil section includes a plurality of layers stacked in the thickness direction of the substrate, with an interval between each other.

Clause 12.

The coil module according to any one of clauses 1 to 11, in which the substrate includes a reverse face opposite to the obverse face, and

the coil section includes a coil formed on the obverse face of the substrate, and a coil formed on the reverse face of the substrate.

Clause 13.

The coil module according to any one of clauses 1 to 12, further including a plurality of terminal sections electrically connected to one of the wiring section and the coil section,

in which the sealing resin includes a face opposite to the substrate, and the plurality of terminal sections are each exposed at the face of the sealing resin.

Clause 14.

The coil module according to any one of clauses 1 to 13, further including an additional coil formed on the coil section,

in which the additional coil overlaps with the coil section, as viewed in the thickness direction of the substrate the substrate.

Clause 15.

An actuator including:

the coil module according to any one of clauses 1 to 14; and

a magnetic field generator opposed to the coil module,

in which the coil module and the magnetic field generator are displaceable relative to each other.

### REFERENCE SIGNS

A10, A11, A12, A20, A21, A30 to A80 coil module

B10 actuator

1 substrate

1′ substrate material

1A obverse face

1B reverse face

11 insulation layer

13 recess

13a bottom face

13b wall face

15 cutout

2 conductor layer

2′ conductor layer

22 mask layer

3 wiring section

4 coil section

4a first section

4b second section

40 additional coil

41 outer coil

41a side

42 inner coil

42a side

43 first coil

43a side

44 second coil

44a side

45 connecting portion

461 lower coil

462 upper coil

471 obverse face coil

472 reverse face coil

481 flat coil

482 inclined coil

51 driver IC

52 chip capacitor

53 Hall element

53a magnetism sensing surface

6, 6a to 6x terminal section

6′ conductive layer

7 sealing resin

7A top face

7B bottom face

80 imaging lens

801 lens barrel

802 lens elements

81 lens holder

82 leaf spring

83 AF coil

84 permanent magnet

85 magnet holder

86 suspension wire

87 flexible substrate

88 coil component

881 coil substrate

882 OIS coil

883 cutout

89 base

89a opening

90 cover

x direction

y direction

z direction (thickness direction of substrate)

1. A coil module comprising:
a substrate including a semiconductor material;
a conductor layer formed on the substrate and including a wiring section, and a coil section of a helical shape;
at least one element mounted on the wiring section; and
a sealing resin covering an obverse surface of the substrate, the conductor layer, and the at least one element.

2. The coil module according to claim 1, wherein the at least one element includes a magnetic detection element.

3. The coil module according to claim 2, wherein the at least one element includes a driver IC, and the magnetic detection element is mounted inside the driver IC.

4. The coil module according to claim 3, wherein the driver IC and the coil section are electrically connected to each other, via the wiring section.

5. The coil module according to claim 2, wherein the at least one element includes a chip capacitor.

6. The coil module according to claim 2, wherein the at least one element is located inside the coil section, as viewed in a thickness direction of the substrate.

7. The coil module according to claim 2, wherein the at least one element is located outside the coil section, as viewed in a thickness direction of the substrate.

8. The coil module according to claim 2, wherein the coil section includes an outer coil, and an inner coil located inside the outer coil as viewed in a thickness direction of the substrate, and
the at least one element is located inside the outer coil, and outside the inner coil, as viewed in the thickness direction of the substrate the substrate.

9. The coil module according to claim 2, wherein the coil section includes a first coil and a second coil connected in series to each other and located side by side as viewed in a thickness direction of the substrate, and
the at least one element is located between the first coil and the second coil, as viewed in the thickness direction of the substrate.

10. The coil module according to claim 2, wherein the substrate is formed with a recess, and
the at least one element is accommodated in the recess.

11. The coil module according to claim 1, wherein the coil section includes a plurality of layers stacked in the thickness direction of the substrate with an interval between each other.

12. The coil module according to claim 1, wherein the substrate includes a reverse face opposite to the obverse face, and
the coil section includes a coil formed on the obverse face of the substrate and another coil formed on the reverse face of the substrate.

13. The coil module according to claim 1, further comprising a plurality of terminal sections electrically connected to one of the wiring section and the coil section,
wherein the sealing resin includes a face opposite to the substrate, and the plurality of terminal sections are each exposed at the face of the sealing resin.

14. The coil module according to claim 1, further comprising an additional coil formed on the coil section,
wherein the additional coil overlaps with the coil section, as viewed in the thickness direction of the substrate.

15. An actuator comprising:
a coil module according to claim 1; and
a magnetic field generator facing the coil module,
wherein the coil module and the magnetic field generator are displaceable relative to each other.
